(19) United States
(12) Patent Application Publication
(10) Pub. No.: US 2025/0236509 A1
(43) Pub. Date: Jul. 24, 2025

(54) MEMS MIRROR MODULE WITH STRESS-DECOUPLED VIBRATIONAL MODES

(71) Applicant: Microsoft Technology Licensing, LLC, Redmond, WA (US)

(72) Inventors: Di SUN, Seattle, WA (US); Matthew David ELLIS, Sammamish, WA (US); Xiangdong QIU, San Jose, CA (US)

(73) Assignee: Microsoft Technology Licensing, LLC, Redmond, WA (US)

(21) Appl. No.: 18/421,837

(22) Filed: Jan. 24, 2024

(51) Int. Cl. B81B 3/00; B81C 1/00; G02B 26/08; G02B 26/10; G02B 27/01

(52) U.S. Cl. CPC B81B 3/0072; B81C 1/00317; G02B 26/0858; G02B 26/105; G02B 27/0172; B81B 2201/042; B81B 2203/0118; B81C 2203/0771; G02B 2027/011

(57) ABSTRACT

A torsional micro-electro-mechanical systems (MEMS) mirror module provides for thermally-stable ancillary modes of mirror oscillation (e.g., vertical, horizontal, and rocking) by utilizing MEMS die packaging techniques that implement a cantilevered (i.e., fixed-free) die package in which one end of the die is partially fixedly-attached to a die carrier substrate while the non-attached end of the die is free from the die carrier substrate and unsupported. The cantilevered die package with fixed-free architecture effectively decouples the effects of coefficient of thermal expansion (CTE) mismatch of the MEMS die, die-bond adhesive, and die carrier substrate on temperature-dependent MEMS flexure stress. Ancillary mode oscillation frequencies changes with temperatures are thus limited to a smaller range relative to those experienced with conventional package designs.

### BACKGROUND

Small oscillating mirrors implemented using micro-electro-mechanical systems (MEMS) technologies are commonly used to reflect imaging light for virtual- and/or mixed-reality scanning imaging systems in head-mounted display (HMD) devices. The mirrors are typically formed from blocks of semiconductor material by removing material from the block around and underneath the mirror while providing for a pair of torsional flexure beams that allow the mirror to oscillate around a lengthwise axis to provide the scanning function.

### SUMMARY

A torsional MEMS mirror module in a scanning display system that is housed in a display module assembly includes a silicon die that is die-attached to a substrate around only a portion of the perimeter of the die to provide for a cantilevered (i.e., fixed-free) die package in which one end of the die is partially fixedly-attached to the substrate while the non-attached end of the die is free from the substrate and unsupported. In an illustrative uniaxial scanner embodiment, the die includes a scanning mirror, which oscillates around a longitudinal axis formed by torsional flexure beams, and piezoelectric actuators to provide controllable beam steering of light from a source such as a laser.

The torsional flexure beams are typically subject to thermally-induced stress experienced during scanner operations from mismatches in the coefficient of thermal expansion (CTE) of the die, substrate, and display module assembly housing. While the scanning mirror and beam flexures are principally designed to operate in a torsional mode, other oscillations of the mirror, termed “ancillary modes,” are possible which include vertical, horizontal, and rocking modes. In conventional designs, the variation in ancillary mode frequency with temperature can be difficult to compensate for through feedback loop control. The present cantilevered die package provides for the die to be partially decoupled from the substrate and display module assembly housing to reduce the impact of CTE mismatch and improve the linearity of MEMS motion, thus improving image quality with feedback loop control across a wide environment temperature range. The approach can also prevent the control loop from the over-driving of the MEMS mirror at ancillary modes which may result in the MEMS flexure beam breakage.

This Summary is provided to introduce a selection of concepts in a simplified form that are further described below in the Detailed Description. This Summary is not intended to identify key features or essential features of the claimed subject matter, nor is it intended to be used as an aid in determining the scope of the claimed subject matter. Furthermore, the claimed subject matter is not limited to implementations that solve any or all disadvantages noted in any part of this disclosure.

### DESCRIPTION OF THE DRAWINGS

FIG. 1 shows a simplified block diagram of an illustrative optical display system usable in a head-mounted display (HMD) device;

FIG. 2 shows an illustrative raster scanning light path for virtual images in an optical display system that includes a pair of uniaxial MEMS mirror modules;

FIG. 3 shows a disassembled view of an illustrative MEMS mirror module;

FIG. 4 shows a top view of an illustrative MEMS mirror module;

FIG. 5 shows an enlarged view of a portion of an illustrative MEMS mirror module;

FIGS. 6 and 7 show operations of an illustrative thin-film piezoelectric actuator;

FIGS. 8 and 9 are pictorial views of an illustrative MEMS mirror module during operation;

FIG. 10 shows illustrative drive signals to a MEMS mirror module;

FIG. 11 shows illustrative MEMS mirror motion in response to drive signals from a controller;

FIG. 12 provides pictorial views of primary and ancillary oscillation modes of a MEMS mirror;

FIGS. 13, 14, and 15 are sectional side views of embodiments of an illustrative MEMS mirror module;

FIGS. 16 and 17 are top views of embodiments of an illustrative MEMS mirror module;

FIG. 18 is a flowchart of an illustrative method for packaging a MEMS module; and

FIG. 19 is a functional block diagram of an illustrative head-mounted display (HMD) device.

Like reference numerals indicate like elements in the drawings. Elements are not drawn to scale unless otherwise indicated.

### DETAILED DESCRIPTION

Micro-electro-mechanical systems (MEMS) devices are commonly used in scanning micromirrors for beam scanning of a laser or other light source. MEMS devices typically comprise integrated circuit dies that are die-attached to a die carrier substrate. Modern MEMS scanners provide high operating frequencies with low-weight and small volume packages which make them well-suited to a variety of applications including, for example, medical imaging such as OCT (Optical Coherence Tomography), LIDAR (Light Detection and Ranging), and optical imaging display systems used in virtual- and mixed-reality head-mounted display (HMD) devices. Other use cases and applications for MEMS scanners using the present principles include, for example and without limitation, manufacturing such as additive fabrication (i.e., 3D printing) using stereo lithography, material processing such as laser marking, engraving, cutting, drilling, and welding, laser projection in entertainment and optical layout template (OLT) scenarios, galvanometer-based image capture, and microscopy, to name just a few of a wide range of MEMS scanning applications.

MEMS torsional scanning mirror designs in imaging applications comprise mirrors that oscillate about torsional flexure beams. For example, in raster-scanning applications requiring bidirectional dual-axis systems, MEMS torsional scanner systems typically utilize a pair of uniaxial scanning mirrors or a biaxial gimbal-mounted scanning mirror. Motion of a MEMS mirror is actuated by various driving methods using, for example, piezoelectric, electromagnetic, electrothermal, and electrostatic technologies.

A principal challenge for bidirectional scanning is the precise control of phase between scan lines and a high-quality control of mirror positioning and motions. When actuators impart the desired torsional oscillation of the mirror about its flexures, the mirror is subject to parasitic, or ancillary modes of oscillation including vertical, horizontal, and rocking (i.e., pitching) modes. Ancillary mode oscillations can result in off-axis mirror motions and cause unwanted beam deflections that can reduce image quality.

MEMS scanning systems can be designed to mitigate the negative effects of the ancillary oscillation modes to some degree. For example, the mirror and flexure beams can be designed to minimize physical cross-coupling between torsion and rocking modes, and/or the actuator drive signals can be modified to compensate for mirror position and motion resulting in the ancillary oscillation modes. Image post-processing may also be utilized in some applications to correct for reduction in image quality.

While the aforementioned mitigation techniques can provide satisfactory results in some cases, the inventors have recognized that ancillary oscillation modes are not thermally stable and their effects on mirror position and motion vary with temperature of the MEMS scanning system during operations. In particular, the frequencies of ancillary mode oscillation have been determined to be dependent on stress in the beam flexures. The inventors have further recognized that the flexure stress is susceptible to changes with MEMS scanner operating temperature because of mismatches in the coefficient of thermal expansion (CTE) of the silicon MEMS die, die-bond adhesive, and the underlying PCB substrate, as well as a display module assembly housing and associated mounting adhesive.

The expansion and contraction of the die, adhesive, and PCB substrate at different magnitudes and rates during operations of the MEMS scanner give rise to a temperature-dependent stress profile in the flexures that, in turn, causes temperature-dependent instability of the ancillary mode oscillation frequencies. Such temperature-dependent variability can be challenging to characterize and may result in undesired ancillary mode effects falling outside the range of constructive mitigation strategies.

The present MEMS mirror module described herein provides for thermally-stable ancillary modes of mirror oscillation by utilizing MEMS die packaging techniques that implement a cantilevered (i.e., fixed-free) die package in which one end of the die is partially fixedly-attached to the substrate while the non-attached end of the die is free from the substrate and unsupported. The cantilevered die package with fixed-free architecture effectively decouples the effects of CTE mismatch of the MEMS die, die-bond adhesive, and PCB substrate on temperature-dependent MEMS flexure stress. Ancillary mode oscillation frequencies changes with temperatures are thus limited to a smaller range relative to those experienced with conventional package designs.

The cantilevered die package used for the present MEMS mirror module advantageously reduces the contribution of CTE mismatch to ancillary mode thermal instability without limiting selection of materials to only those having similar CTEs. In addition, current MEMS manufacturing and assembly processes are readily adaptable for the cantilevered die package with minimal modifications.

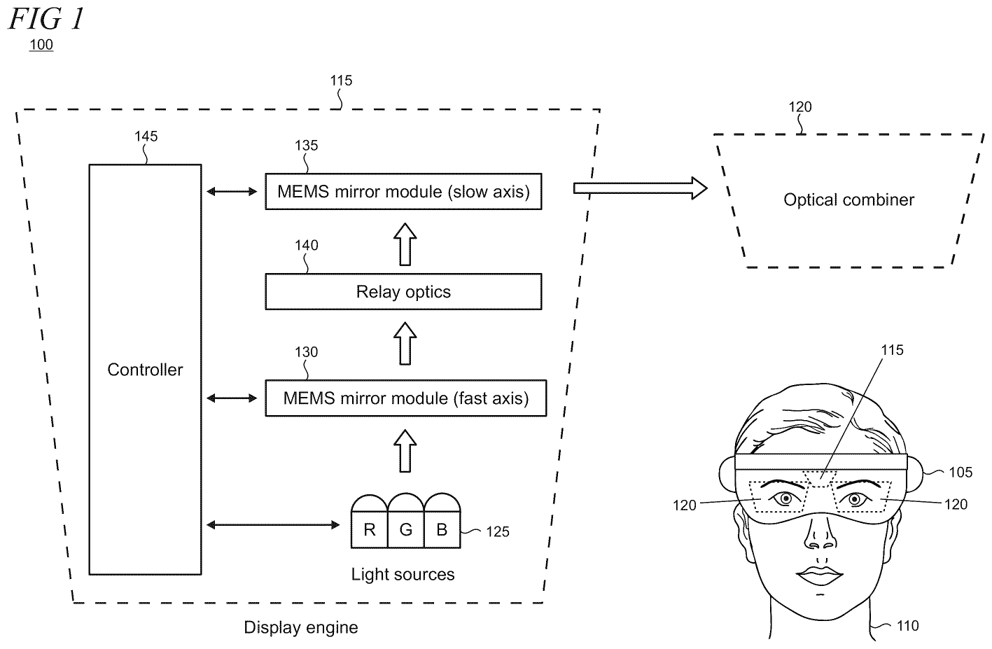

Turning now to the drawings, FIG. 1 shows a simplified block diagram of an illustrative projection-based optical display system 100 usable in a head-mounted display (HMD) device 105 worn by a user 110. In this illustrative example, the HMD device is a mixed-reality device in which images of virtual objects are superimposed over the user's view of the real physical world. However, it may be appreciated that the present principles disclosed herein are applicable to virtual-reality HMD and other devices.

The optical display system 100 includes a display engine 115 that interoperates with a see-through optical combiner 120, through which the user 110 looks, to combine virtual images generated by the display engine with views of the real world. Typically, a separate optical combiner is provided by the HMD device for each of the user's eyes. For example, the display engine and left- and right-eye optical combiners can work together to support stereoscopic virtual images.

The display engine 115 includes a pair of uniaxial MEMS mirror modules that implement a raster scanning system by which light for virtual images from a light source 125 is guided to create an exit pupil for the display system 100 which is replicated (i.e., expanded) by the optical combiner 120. The MEMS mirror modules include a fast axis module 130 and a slow axis module 135. In typical applications, relay optics 140 such as lenses and reflectors are utilized between the fast axis and slow axis MEMS mirror modules to facilitate guiding of the virtual image light through the display engine. For example, the relay optics can shape the virtual image light beams and/or fold the light path within the display engine to implement a desired form factor.

The light source 125 is implemented using red, green, and blue (RGB) lasers in this illustrative example to support polychromatic virtual imaging using an RGB color space. In alternative embodiments, monochromatic virtual imaging may be utilized and/or different color spaces used. A controller 145 in the display engine provides control signals for the light source and MEMS mirror modules 130 and 135. Separate controllers may be alternatively utilized. The controller may also be alternatively incorporated into another controller or processor in the HMD device 105 such as a main or central processing unit (CPU) or other suitable processor.

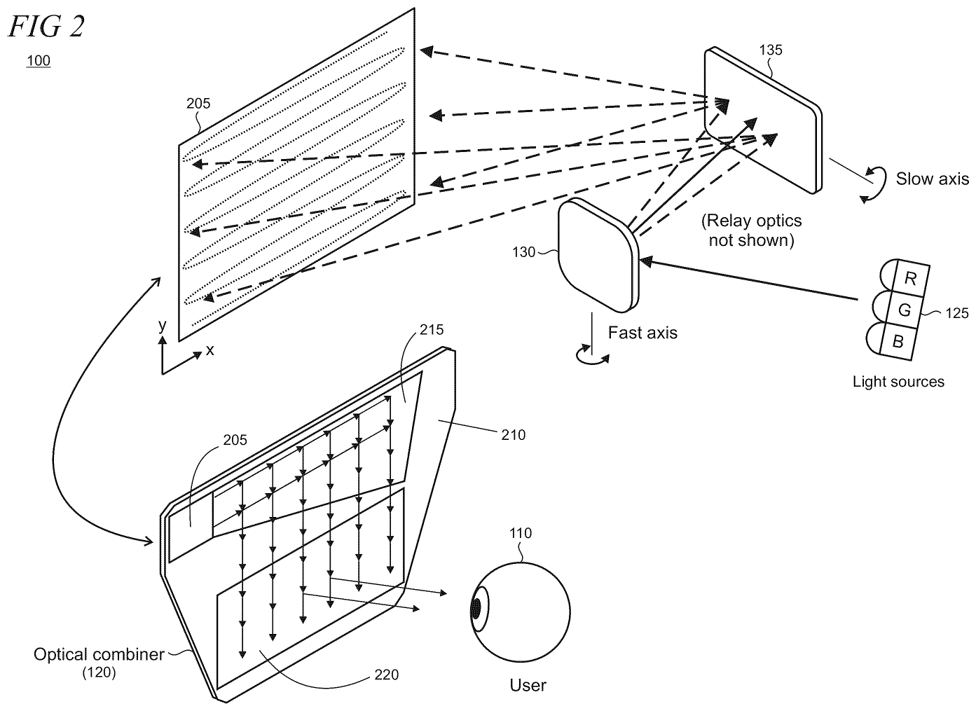

FIG. 2 shows an illustrative raster scanning light path for virtual images in the optical display system 100. Raster scanning is utilized to illustrate the present principles, however, other scanning techniques are utilizable to meet the needs of a given implementation. Raster scanning is a commonly utilized technique in which a low frequency, saw-tooth ramp vertical scanning is paired with an associated high frequency sinusoidal horizontal scanning using the respective slow and fast axis MEMS mirror modules 135 and 130. Raster scanning uses a sinusoidal pattern along the x-axis that is shifted downwards, in steps or continuously, along the y-axis.

The scanned virtual image light creates an exit pupil on an input element 205 to the optical combiner 120. The input element is disposed on a see-through waveguide 210. In this illustrative example, the exit pupil is expanded in the horizontal and vertical directions in the optical combiner to increase the size of the eyebox of the optical combiner for rendered virtual images. An expanding element 215 disposed on the waveguide expands the virtual image exit pupil horizontally while coupling the virtual image light downwards to an output element 220 that is disposed on the waveguide. The output element expands the exit pupil vertically and outcouples the virtual images to the user 110. In an illustrative example, the input, expanding, and output elements are implemented as diffractive optical elements (DOEs), reflective optical elements (ROEs), or a combination of DOEs and ROEs.

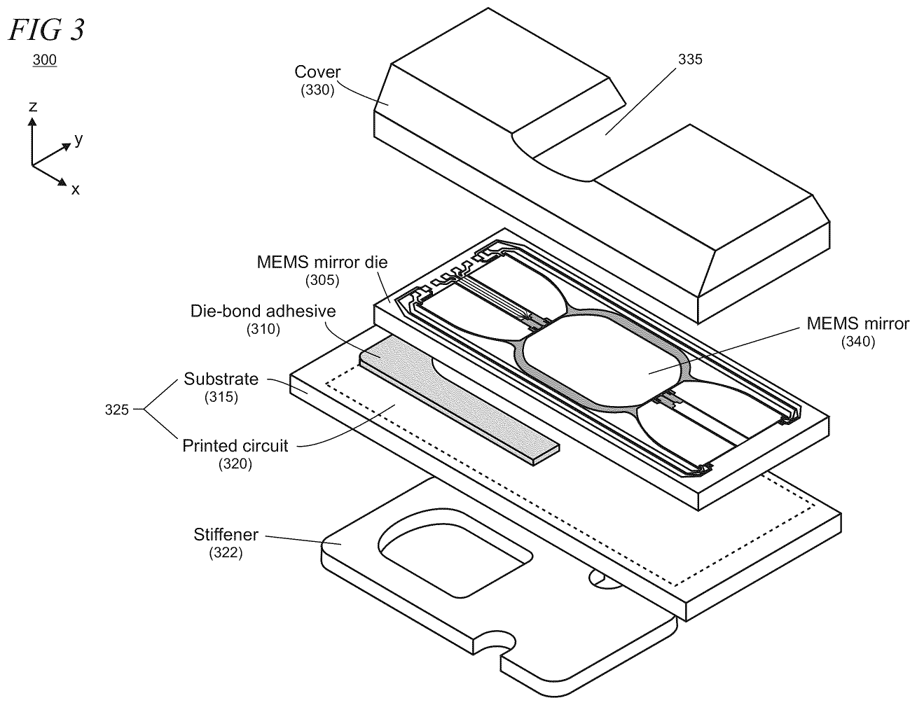

FIG. 3 shows a disassembled view of an illustrative MEMS mirror module 300 that is arranged in accordance with the present principles. The module comprises MEMS mirror die 305 implemented as a silicon semiconductor that is die-attached with a die-bond adhesive 310 to a ceramic substrate 315. The substrate includes a printed circuit 320 (the combination of substrate and printed circuit is referred to herein as die carrier substrate 325). A stiffener 322 is provided to support the die carrier substrate and may be affixed to the die carrier substrate using a suitable adhesive (not shown) or other fastening elements or methods. A cover 330 is utilized to provide physical protection to the MEMS mirror die and includes an opening 335 or optically transparent window through which a MEMS mirror 340 is operated to steer virtual image light.

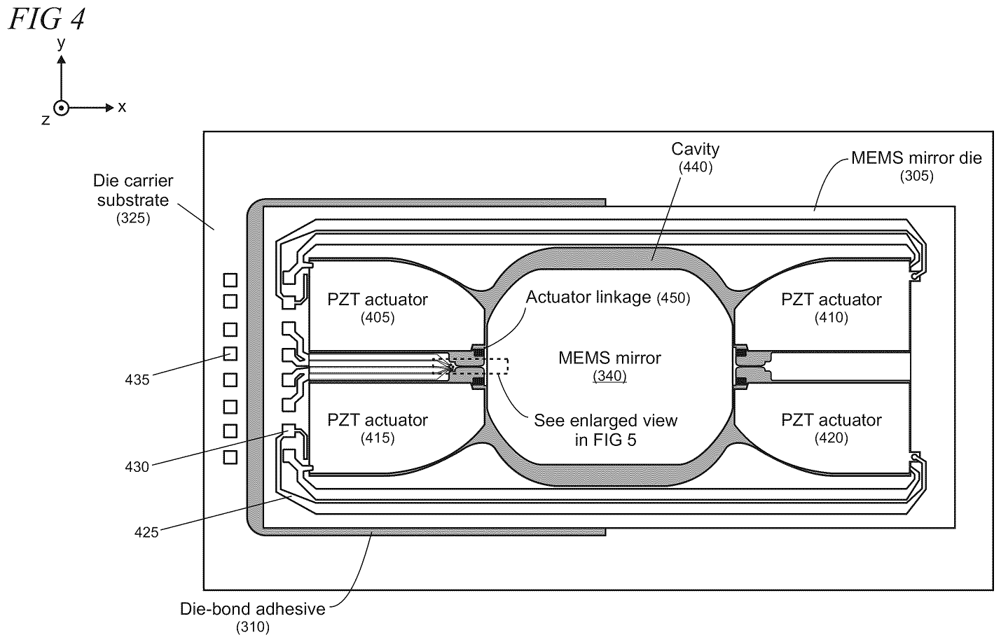

FIG. 4 shows a top view of the illustrative MEMS mirror die 305 that is die-attached via die-bond adhesive 310 to the die carrier substrate 325 (the module cover is not shown for clarity). The mirror die includes the mirror 340 that is actuated by PZT (lead-zirconate-titanate) actuators which operate in two pairs of two (indicated by reference numerals 405, 410, 415, and 420), as discussed below. The PZT actuators are mechanically coupled to the mirror to impart motion via suitable actuator linkages (as representatively indicated by reference numeral 450. The MEMS mirror die includes various circuits (representatively indicated by reference numeral 425) and pads (430) that are wire-bonded to corresponding pads (435) on the die carrier substate 325 (the wire-bonds are not shown).

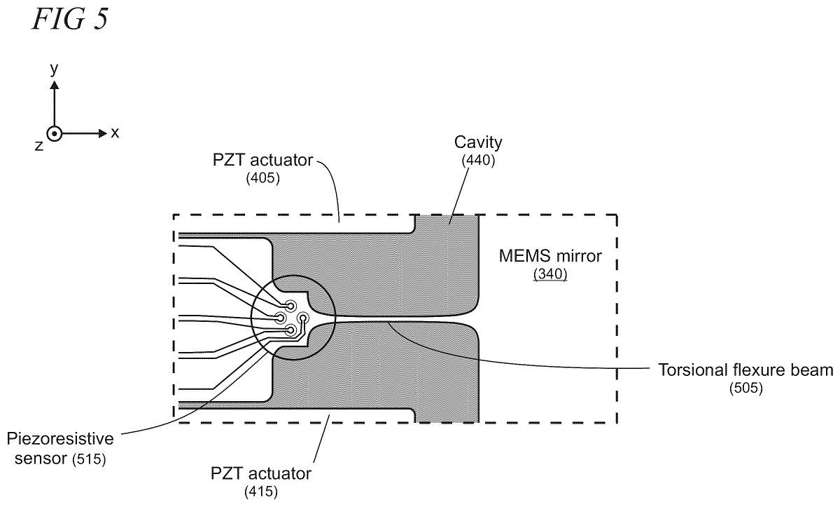

The MEMS mirror 340 is configured to provide torsional oscillations in a uniaxial arrangement in this illustrative example. The MEMS mirror is suspended over a cavity 440 in the module by a torsional flexure beam at each end of the mirror. A representative flexure beam 505 is shown in the enlarged view in FIG. 5. A piezoresistive sensor 515 is utilized in this illustrative example to provide a mirror position signal to the controller 145 (FIG. 1) which may be utilized to implement various control and monitoring systems.

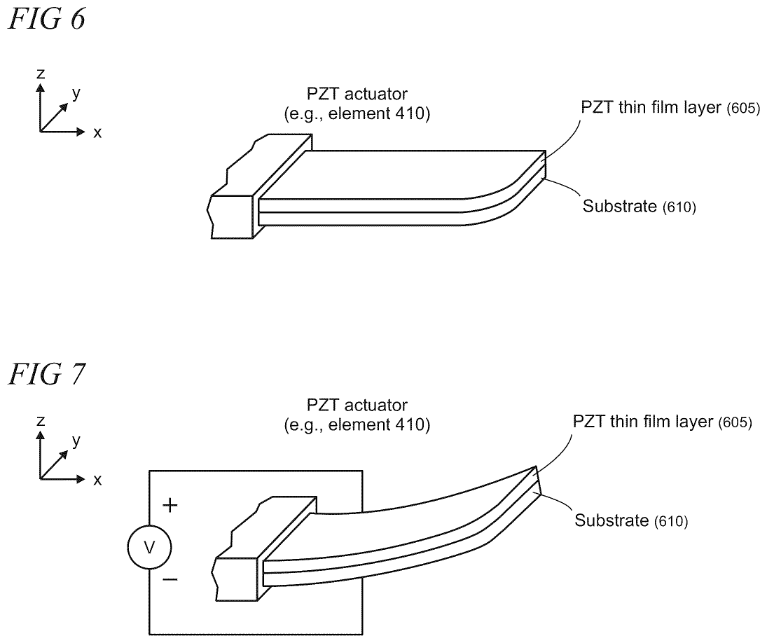

In this illustrative example, the PZT actuators are implemented using piezoelectric methodologies. A thin film layer of PZT 605 is disposed on an actuator substrate 610, as shown in FIG. 6. When a voltage is applied to the actuator, the PZT layer shrinks, which causes the actuator substrate to elastically deform, as shown in FIG. 7.

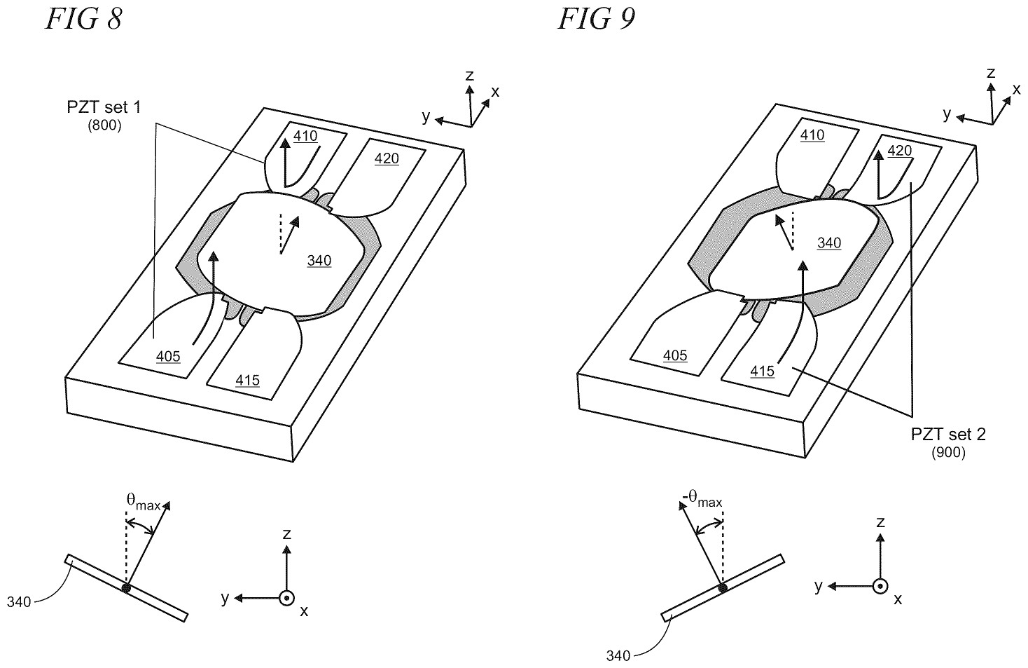

The PZT actuators are utilized in pairs to actuate the torsional oscillations of the MEMS mirror 340 (FIG. 3). FIGS. 8 and 9 are pictorial views of the illustrative MEMS mirror module 300 during operation. As shown in FIG. 8, PZT actuators 405 and 410 operate as a PZT set 1 (as indicated by reference numeral 800). In response to an applied voltage signal to PZT set 1, the ends of PZT actuators move upwards, as indicated by the arrows.

The upward motions of the actuators in PZT set 1 provide a force through the respective actuator linkages 450 (FIG. 4) that causes the MEMS mirror 340 to tilt to the right over an angular range from a projected normal that is bounded by θₘₐₓ. Similarly, as shown in FIG. 9, PZT actuators 415 and 420 operate as a PZT set 2 (as indicated by reference numeral 900). In response to an applied voltage signal to PZT set 2, the ends of the PZT actuators move upwards, as indicated by the arrows. The upward motions of the actuators in PZT set 2 provide a force through the respective actuator linkages that causes the MEMS mirror 340 to tilt to the left over an angular range from a projected normal that is bounded by −θₘₐₓ.

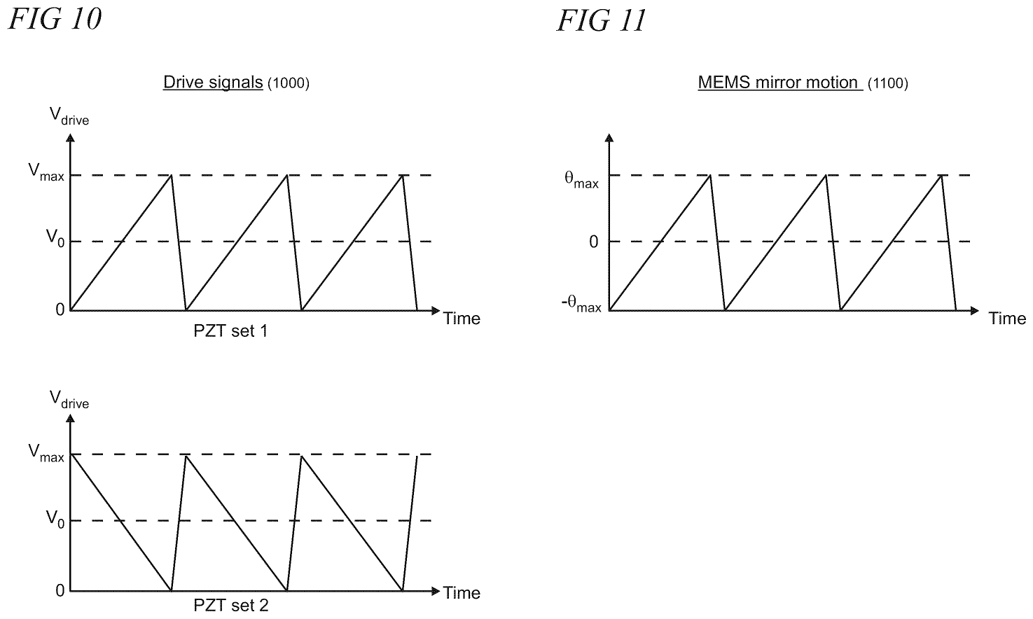

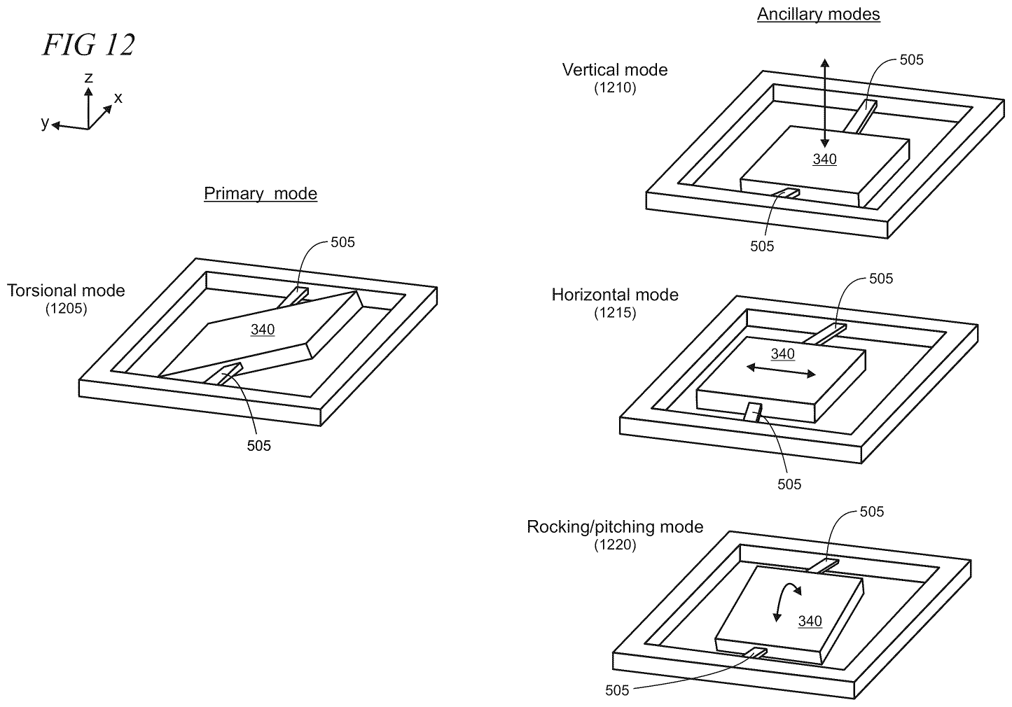

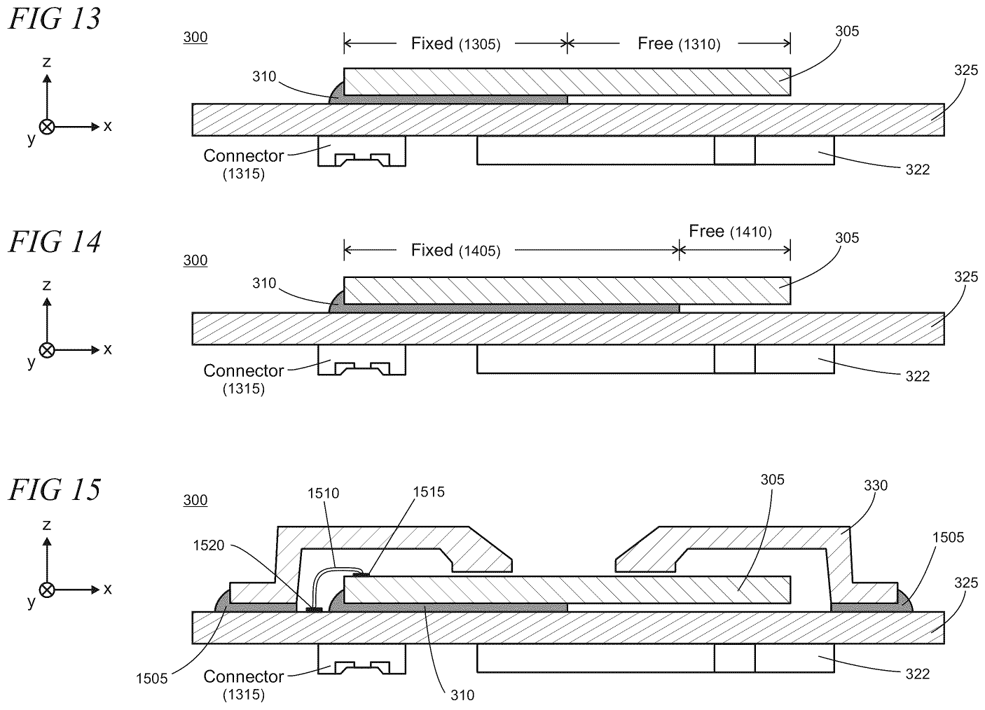

The PZT actuators in sets 1 and 2 operate according to drive signals that are received from the controller 145 (FIG. 1). FIG. 10 shows illustrative drive signal waveforms 1000. The waveforms typically comprise triangular or saw-tooth ramp patterns to cause suitable mirror positioning and motion to perform raster scanning. As shown, full positive voltage signals are alternately provided to the PZT actuator sets which results in the torsional MEMS mirror motion shown in the graph 1100 in FIG. 11 and the pictorial view in FIG. 12. As shown, the mirror 340 oscillates about the flexure beams 505.

While the torsional mode 1205 is the desired principal mode of MEMS mirror operation, unwanted parasitic vibrational modes, termed “ancillary modes” can be induced primarily by the saw-tooth ramp drive signals that actuate the motion of the MEMS mirror in the module. The drive signals typically include harmonics that are the same, or similar to, the ancillary mode frequencies. The ancillary modes include vertical, horizontal, and rocking (i.e., pitching) modes 1210, 1215, and 1220, as shown in FIG. 12. The ancillary modes of mirror oscillation can cause a variety of issues in conventional projection-based display systems including, for example, reductions in obtainable drive amplitudes and failures of mechanical structures through deflections that cause high mechanical stress. In addition, off-axis mirror motions in the ancillary modes can result in poor control of mirror positioning and cause degradation in image quality below a level that can be mitigated, for example, through tuning of the drive signals.

The ancillary modes also produce strain on the piezoresistive sensor 515, creating signals in the control loop to which the drive system responds. These unwanted signals are filtered out using notch filters that suppress the signal response in specific frequency bands. The ancillary mode frequency shifts with temperature due to CTE mismatch in the MEMS modules present challenges for control system design.

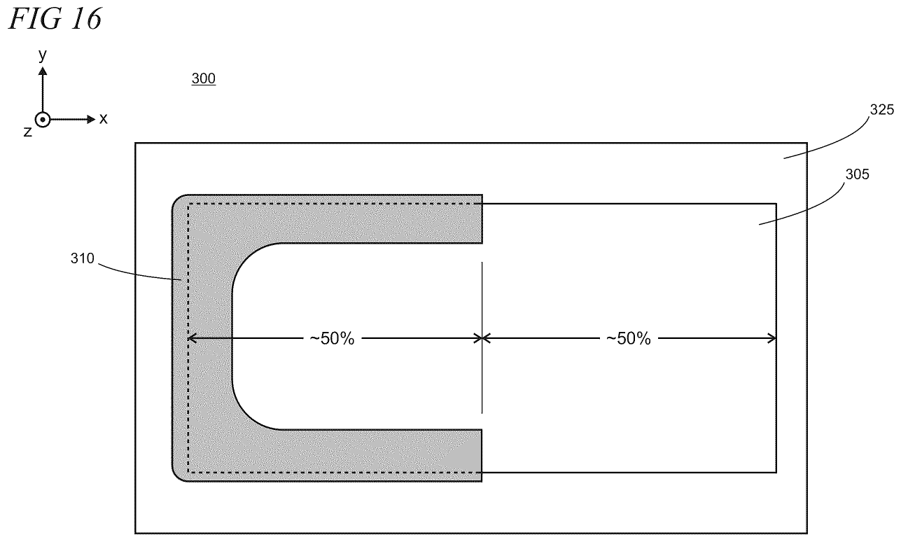

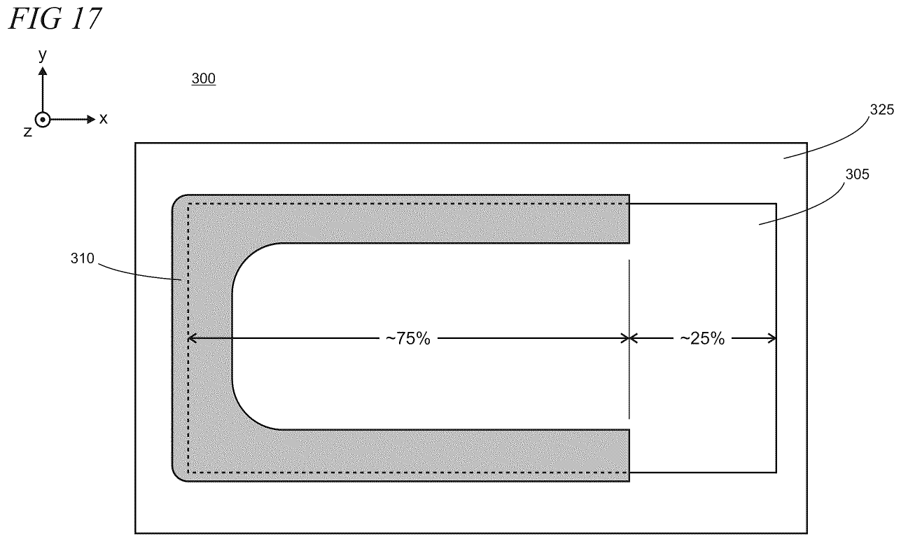

FIGS. 13, 14, and 15 are sectional side views of illustrative embodiments of the MEMS mirror module 300 that utilize a cantilevered die package that at least partially decouples the MEMS mirror die 305 from the die carrier substrate 325. As shown, an electrical connector 1315 is provided at the bottom of the die carrier substrate adjacent to the stiffener 322. FIGS. 13 and 14 show the mirror module without the cover 330. FIG. 15 shows the cover assembled to the module using, for example, an edge-bonding adhesive 1505 or suitable gasket. Wire-bonds 1510 between respective pads 1515 and 1520 on the die and die carrier substrate are also shown. The die-bond adhesive layer 310 is configured to extend under the portion of the MEMS mirror die to ensure integrity of the wire-bonds. FIGS. 16 and 17 are top views of illustrative embodiments of the MEMS mirror module.

FIGS. 13 and 16 show a first illustrative embodiment in which the die-bond adhesive layer 310 extends approximately 50 percent along the long edge of the MEMS mirror die 305 to provide a fixed end 1305 of the die and a free end 1310. As shown in the top view in FIG. 16, the die-bond adhesive layer is disposed along a partial perimeter of the fixed end of the MEMS mirror die in the shape of a “C” that is elongated in the direction of the long axis of the die. FIGS. 14 and 17 show a second illustrative embodiment in which the die-bond adhesive layer 310 extends approximately 75 percent along the long edge of the MEMS mirror die 305 to provide a fixed end 1405 of the die and a free end 1410. The fixed-free die architecture provided by the cantilevered die package increases the MEMS mirror module's resistance to stress variations in the torsional flexure beams. As noted above, such stress variations may occur from mismatched CTE of module components including the die 305, die carrier substrate 325, and die-bond adhesive layer 310.

It is emphasized that the embodiments shown in the drawings and described in the accompanying text are illustrative and not limiting. Variations in the extent of the die-bond adhesive layer are utilizable to meet the requirements of a particular implementation of the present principles.

The die-bond adhesive layer 310 may comprise a variety of materials and be applied using different techniques. In the illustrative embodiments of the MEMS mirror module 300 shown in FIGS. 13-17, the die-bond adhesive comprises a curable epoxy material, such as silver epoxy glass or a polyimide-based material, that is applied using known semiconductor edge bonding techniques around the partial perimeter of the fixed end of the MEMS mirror die 305. Edge bonding is typically utilized in applications in which the MEMS mirror module is exposed to high temperature cycling and/or environmental conditions having high levels of shock and vibration. As shown, the edge bonding feature penetrates under the die to ensure proper mechanical bonding between the die and the die carrier substrate. Epoxy edge bonding is generally removable in reworking scenarios by application of heat and mechanical scraping. Other die-bond adhesives and die-bonding techniques that may be suitable to a given MEMS mirror module design include eutectic and solder die-attachments.

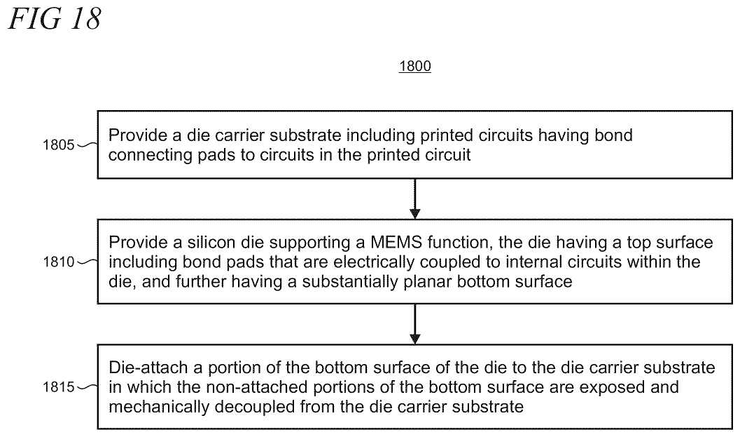

FIG. 18 is a flowchart of an illustrative method 1800 for packaging a MEMS module. Unless specifically stated, methods or steps shown in the flowchart blocks and described in the accompanying text are not constrained to a particular order or sequence. In addition, some of the methods or steps thereof can occur or be performed concurrently and not all the methods or steps have to be performed in a given implementation depending on the requirements of such implementation and some methods or steps may be optionally utilized.

Block 1805 includes providing a die carrier substrate including printed circuits having bond connecting pads to circuits in the printed circuit. Block 1810 includes providing a silicon die supporting a MEMS function, the die having a top surface including bond pads that are electrically coupled to internal circuits within the die, and further having a substantially planar bottom surface. Block 1815 includes die-attaching a portion of the bottom surface of the die to the die carrier substrate, in which the non-attached portions of the bottom surface are exposed and mechanically decoupled from the die carrier substrate.

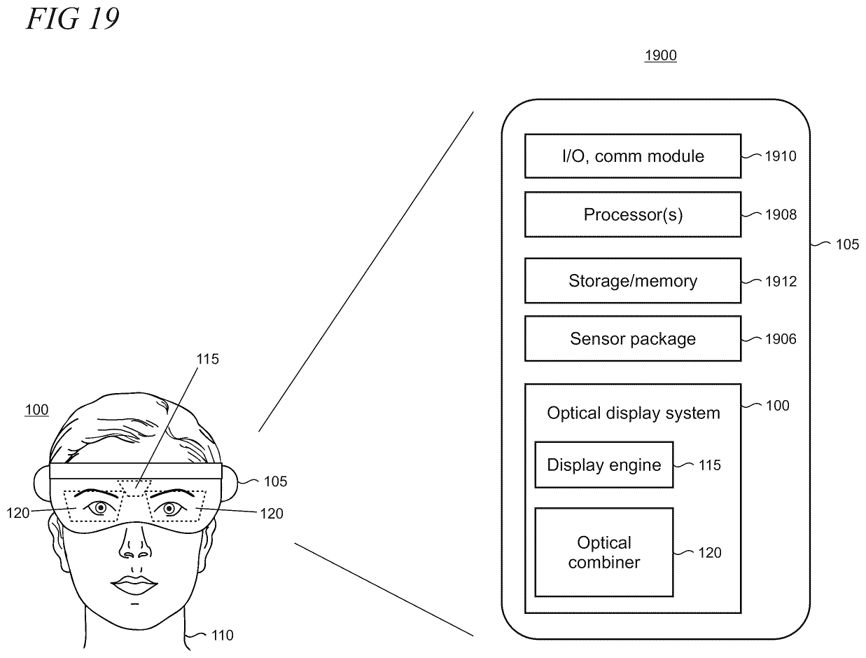

FIG. 19 is a functional block diagram 1900 of the illustrative HMD device 105. The HMD device includes the display system 100 comprising a display engine 115 and optical combiner 120, as described above. The HMD device further comprises a sensor package 1906 that may comprise devices such as cameras, microphones, biometric and depth sensors, and the like to facilitate implementation of various features and capabilities in the HMD device including, for example, gaze and body tracking, position and motion sensing, and the like.

The HMD device 105 further includes one or more processors 1908 which may include the functionality of the controller 145 (FIG. 1) or be separately instantiated from the controller. An input/output (I/O) and communications system module 1910 facilitates the HMD device being operated in conjunction with remotely located resources, such as processing, storage, power, data, and services. That is, in some implementations, an HMD device is operable as part of a system that distributes resources and capabilities among different components and systems.

Storage and memory system 1912 includes instructions stored thereon that are executable by the processors 1908. The storage system includes hardware storage devices, such as RAM, ROM, EEPROM, CD-ROM, solid state drives (SSDs) that are based on RAM, Flash memory, phase-change memory (PCM), or other types of memory, or other optical disk storage, magnetic disk storage or other magnetic storage devices, or any other medium that can be used to store desired program code means in the form of computer-executable instructions, data, or data structures and that can be accessed as required for the HMD device to implement the various features and functionality described herein.

It may be appreciated that the HMD device 105 is described for the purpose of example, and thus is not meant to be limiting. It may be further understood that the HMD device includes, in some embodiments, additional and/or alternative sensors, cameras, microphones, input devices, output devices, etc. than those shown without departing from the scope of the present arrangement. Additionally, the physical configuration of an HMD device and its various sensors and components may take a variety of different forms without departing from the scope of the present arrangement.

Various exemplary embodiments of the present MEMS mirror module with stress-decoupled vibrational modes are now presented by way of illustration and not as an exhaustive list of all embodiments. An example includes a MEMS (micro-electro-mechanical system) mirror module, comprising: a die carrier substrate including a die-bonding surface; a silicon die disposed on the die-bonding surface of the die carrier substrate, the die including a MEMS mirror that is suspended by torsional flexures; and a die-bond adhesive layer, disposed between a proximal end of the die and the die-bonding surface of the die carrier substrate, that fixedly attaches the proximal end of the die to the die-bonding surface of the die carrier substrate, and in which a distal end of the die is free-floating above the die-bonding surface of the die carrier substrate.

In another example, the die carrier substrate includes a printed circuit and a stiffener that is affixed to the die carrier substrate using an adhesive. In another example, the MEMS mirror module further includes wire bonds between the die and the printed circuit. In another example, the die-bond adhesive layer is disposed around a portion of a perimeter of the proximal end of the die. In another example, the die-bond adhesive layer is disposed along a portion of a perimeter edge of the proximal end of the die, the perimeter edge being parallel to a longitudinal axis of the torsional flexures. In another example, a length of the die-bond adhesive layer that is disposed along a portion of a perimeter edge of the proximal end of the die is between approximately 50 and 75 percent of a length of the die carrier substrate. In another example, the MEMS mirror module further comprises one or more piezoelectric actuators. In another example, the MEMS mirror is configured as a uniaxial scanning mirror. In another example, the MEMS mirror module is used in an optical scanning display system of a head-mounted display (HMD) device. In another example, the die has a coefficient of thermal expansion (CTE) that is different from a CTE of the die carrier substrate. In another example, the MEMS mirror includes a principal torsional mode of operation and a plurality of ancillary operation modes, and in which the free-floating distal end of the die provides for thermally-stable ancillary operation modes.

A further example includes a cantilevered semiconductor die package, comprising: a die carrier substrate having a die-attach surface; a semiconductor die having a fixed end that is fixedly die-attached to the die carrier substrate and a free end that is unattached to the die carrier substrate; and a die-bonding material forming a layer between the die carrier substrate and the die, the layer providing a mechanical connection between the die and the die carrier substrate, and the die-bonding material further functioning as a standoff that elevates the free end of the die above the die-attach surface of the die carrier substrate.

In another example, the die is a MEMS (micro-electro-mechanical system) die providing functions including one of sensor, oscillator, scanner, or actuator. In another example, the elevated free end of the die at least partially decouples the die and the die carrier substrate when the die and die carrier substrate undergo thermal expansion during electrical operation of the die. In another example, the die-bonding material functioning as the standoff has a “C” shape in plan view. In another example, the die-bonding material comprises one of adhesive bonding material, eutectic bonding material, or solder.

A further example includes a method for packaging a MEMS (micro-electro-mechanical system) module, comprising: providing a die carrier substrate including printed circuits having bond connecting pads to circuits in the printed circuit; providing a silicon die supporting a MEMS function, the die having a top surface including bond pads that are electrically coupled to internal circuits within the die, and further having a substantially planar bottom surface; and die-attaching a portion of the bottom surface of the die to the die carrier substrate, in which the non-attached portions of the bottom surface are exposed and mechanically decoupled from the die carrier substrate.

In another example, the die includes flexures and the mechanical decoupling of non-attached portions from the die carrier substrate decouples stress in the flexures from thermally-induced strain in the die carrier substrate and die. In another example, the method further includes performing wire bonding between respective bond pads on the die and printed circuit to create electrical interconnections between the die and the printed circuits. In another example, the MEMS function includes optical scanning using a mirror that is included in the die.

Although the subject matter has been described in language specific to structural features and/or methodological acts, it is to be understood that the subject matter defined in the appended claims is not necessarily limited to the specific features or acts described above. Rather, the specific features and acts described above are disclosed as example forms of implementing the claims.

What is claimed:

1. A MEMS (micro-electro-mechanical system) mirror module, comprising:
a die carrier substrate including a die-bonding surface;
a silicon die disposed on the die-bonding surface of the die carrier substrate, the die including a MEMS mirror that is suspended by torsional flexures; and
a die-bond adhesive layer, disposed between a proximal end of the die and the die-bonding surface of the die carrier substrate, that fixedly attaches the proximal end of the die to the die-bonding surface of the die carrier substrate, and in which a distal end of the die is free-floating above the die-bonding surface of the die carrier substrate.

2. The MEMS mirror module of claim 1 in which the die carrier substrate includes a printed circuit and in which a stiffener is affixed to the die carrier substrate using an adhesive.

3. The MEMS mirror module of claim 2 further including wire bonds between the die and the printed circuit.

4. The MEMS mirror module of claim 1 in which the die-bond adhesive layer is disposed around a portion of a perimeter of the proximal end of the die.

5. The MEMS mirror module of claim 1 in which the die-bond adhesive layer is disposed along a portion of a perimeter edge of the proximal end of the die, the perimeter edge being parallel to a longitudinal axis of the torsional flexures.

6. The MEMS mirror module of claim 5 in which a length of the die-bond adhesive layer that is disposed along a portion of a perimeter edge of the proximal end of the die is between approximately 50 and 75 percent of a length of the die carrier substrate.

7. The MEMS mirror module of claim 1 further comprising one or more piezoelectric actuators.

8. The MEMS mirror module of claim 1 in which the MEMS mirror is configured as a uniaxial scanning mirror.

9. The MEMS mirror module of claim 1 as used in an optical scanning display system of a head-mounted display (HMD) device.

10. The MEMS mirror module of claim 1 in which the die has a coefficient of thermal expansion (CTE) that is different from a CTE of the die carrier substrate.

11. The MEMS mirror module of claim 10 in which the MEMS mirror includes a principal torsional mode of operation and a plurality of ancillary operation modes, and in which the free-floating distal end of the die provides for thermally-stable ancillary operation modes.

12. A cantilevered semiconductor die package, comprising:
a die carrier substrate having a die-attach surface;
a semiconductor die having a fixed end that is fixedly die-attached to the die carrier substrate and a free end that is unattached to the die carrier substrate; and
a die-bonding material forming a layer between the die carrier substrate and the die, the layer providing a mechanical connection between the die and the die carrier substrate, and the die-bonding material further functioning as a standoff that elevates the free end of the die above the die-attach surface of the die carrier substrate.

13. The cantilevered semiconductor die package of claim 12 in which the die is a MEMS (micro-electro-mechanical system) die providing functions including one of sensor, oscillator, scanner, or actuator.

14. The cantilevered semiconductor die package of claim 12 in which the elevated free end of the die at least partially decouples the die and the die carrier substrate when the die and the die carrier substrate undergo thermal expansion during electrical operation of the die.

15. The cantilevered semiconductor die package of claim 12 in which the die-bonding material functioning as the standoff has a “C” shape in plan view.

16. The cantilevered semiconductor die package of claim 12 in which the die-bonding material comprises one of adhesive bonding material, eutectic bonding material, or solder.

17. A method for packaging a MEMS (micro-electro-mechanical system) module, comprising:
providing a die carrier substrate including printed circuits having bond connecting pads to circuits in the printed circuit;
providing a silicon die supporting a MEMS function, the die having a top surface including bond pads that are electrically coupled to internal circuits within the die, and further having a substantially planar bottom surface; and
die-attaching a portion of the bottom surface of the die to the die carrier substrate, in which the non-attached portions of the bottom surface are exposed and mechanically decoupled from the die carrier substrate.

18. The method of claim 17 in which the die includes flexures and the mechanical decoupling of non-attached portions from the die carrier substrate decouples stress in the flexures from thermally-induced strain in the die carrier substrate and die.

19. The method of claim 17 further including performing wire bonding between respective bond pads on the die and printed circuit to create electrical interconnections between the die and the printed circuits.

20. The method of claim 17 in which the MEMS function includes optical scanning using a mirror that is included in the die.
